(19) United States
(12) Patent Application Publication
(10) Pub. No.: US 2026/0136565 A1
(43) Pub. Date: May 14, 2026

(54) STACKED MEMORY DEVICES

(71) Applicant: SK hynix Inc., Icheon-si Gyeonggi-do (KR)

(72) Inventor: Joon Yong CHOI, Icheon-si Gyeonggi-do (KR)

(73) Assignee: SK hynix Inc., Icheon-si Gyeonggi-do (KR)

(21) Appl. No.: 19/317,348

(22) Filed: Sep. 3, 2025

Related U.S. Application Data
(60) Provisional application No. 63/720,380, filed on Nov. 14, 2024.
(60) Provisional application No. 63/828,634, filed on Jun. 23, 2025.

(51) Int. Cl. H10B 80/00; H01L 25/065; H01L 25/18

(52) U.S. Cl. CPC H10B 80/00; H10W 90/00; H10W 90/288; H10W 90/291; H10W 90/297; H10W 90/722; H10W 90/724

(57) ABSTRACT

A stacked memory device includes a first die including a first region and a second region, the first die being on a plane defined by a first direction and a second direction, and a die group stacked on the second region. A first layer is disposed beneath the first region, the first layer controlling transmission of signals between the die group and a processor through a plurality of channels, and an empty space is provided over on the first region.

### CROSS-REFERENCE TO RELATED APPLICATIONS

The present application claims benefit under 35 U.S.C. § 119 (e) to U.S. Provisional Application No. 63/720,380, filed on Nov. 14, 2024, and No. 63/828,634, filed on Jun. 23, 2025, the entire contents of which applications are incorporated herein by reference.

### BACKGROUND

### 1. Technical Field

The present disclosure relates to stacked memory devices that efficiently dissipate heat.

### 2. Related Art

Recently, stacked memory systems such as high bandwidth memory (HBM) devices are used in a wide range of applications due to their high bandwidth and energy efficiency. Unlike conventional memory systems that use parallel data buses, the stacked memory system includes a stacked memory device including a base chip and a plurality of memory chips interconnected by through silicon vias (TSVs). The stacked memory device includes a physical interface, such as a physical layer to communicate with a processor. The physical layer is designed for high-speed data transmission and efficient communication.

### SUMMARY

The present disclosure provides a stacked memory device that may include a first die including a first region and a second region, the first die being on a plane defined by a first direction and a second direction, and a die group stacked on the second region. A first layer may be disposed beneath the first region, the first layer controlling transmission of signals between the die group and a processor through a plurality of channels. An empty space may be set over the first region.

The present disclosure provides a stacked memory device that may include a first die including a first region and a second region, the first die being on a plane defined by a first direction and a second direction, and a die group stacked on the second region. A first layer may be disposed beneath the first region, the first layer controlling transmission of signals between the die group and a processor through a plurality of channels. A first dummy die group may be stacked on the first region.

The present disclosure provides a stacked memory device that may include a first die including a first region and a second region, the first die being on a plane defined by a first direction and a second direction, and a core die group stacked on the second region in a first direction. A first layer may be disposed beneath the first region, the first layer controlling transmission of signals between the die group and a processor through a plurality of channels. A first dummy die may be disposed on the first region.

### BRIEF DESCRIPTION OF THE DRAWINGS

FIG. 1 illustrates a stacked memory device according to an embodiment of the present disclosure.

FIG. 2 illustrates an example of the arrangement of regions included in a base die.

FIG. 3 illustrates a stacked memory device according to an embodiment of the present disclosure.

FIG. 4 illustrates a stacked memory device according to an embodiment of the present disclosure.

FIG. 5 to FIG. 8 illustrate examples of the arrangement of regions included in base dies.

FIG. 9 illustrates a stacked memory system according to an embodiment of the present disclosure.

### DETAILED DESCRIPTION

Terms such as “first” and “second” are used to distinguish between various elements and do not imply size, order, priority, quantity, or importance of the elements. For example, a first element may be named as a second element in one example, and the second element may be named as a first element in another example.

When one component is identified as “connected” to another component, the components may be connected directly or through an intervening component between the components. When two components are identified as “directly connected,” one component is directly connected to the other component without an intervening component between the two components.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

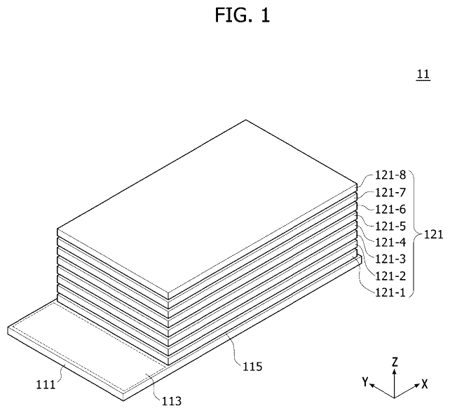

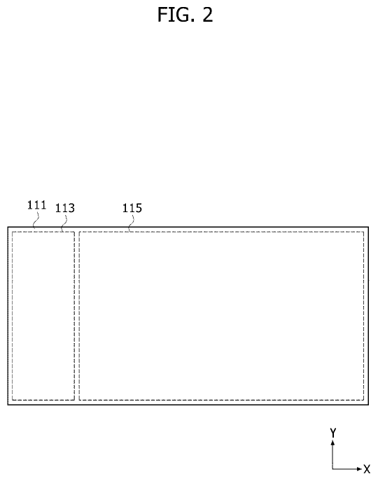

FIG. 1 illustrates a stacked memory device 11 according to an embodiment of the present disclosure, and FIG. 2 illustrates an example of the arrangement of a first region 113 and a second region 115 included in a base die 111.

As shown in FIG. 1, the stacked memory device 11 includes the base die 111 and a core die group 121. As shown in FIG. 1 and FIG. 2, the first region 113 and the second region 115 refer to regions on the XY plane of the base die 111. The first region 113 and the second region 115 are sequentially arranged adjacent to each other in the X direction.

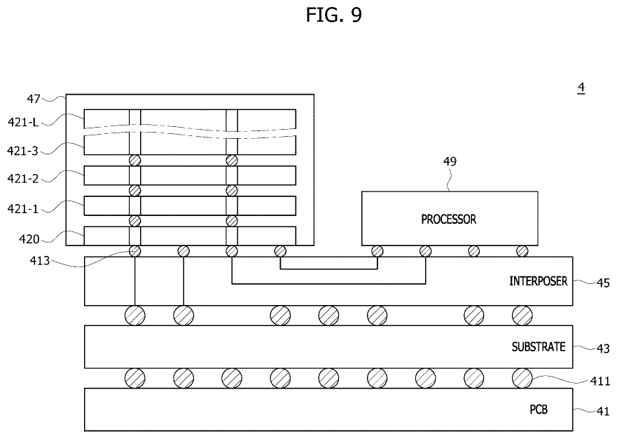

A physical layer that controls transmission of signals (for example, data, commands, and addresses) through a plurality of channels between the core die group 121 and a processor (for example, a processor 49 in FIG. 9) may be disposed beneath the first region 113 of the base die 111. According to embodiments, circuits that operate in a high-temperature state due to frequent input/output of signals among internal circuits included in the base die 131 may be disposed beneath the first region 113 of the base die 111. No structure that dissipates heat is stacked in the Z direction from the first region 113 of the base die 111. That is, an empty space is provided in the Z direction from the first region 113 of the base die 111. Thus, heat generated when the internal circuits, located beneath the first region 113 of the base die 111, operate can be dissipated in the Z direction from the first region 113.

A plurality of core dies 121-1 through 121-8 of the core group 121 are stacked in the Z direction from the second region 115. The core group 121 includes a first core die 121-1, a second core die 121-2, a third core die 121-3, a fourth core die 121-4, a fifth core die 121-5, a sixth core die 121-6, a seventh core die 121-7, and an eighth core die 121-8. The first core die 121-1 is stacked in the Z direction from the second region 115, the second core die 121-2 is stacked in the Z direction from the first core die 121-1, the third core die 121-3 is stacked in the Z direction from the second core die 121-2, the fourth core die 121-4 is stacked in the Z direction from the third core die 121-3, the fifth core die 121-5 is stacked in the Z direction from the fourth core die 121-4, the sixth core die 121-6 is stacked in the Z direction from the fifth core die 121-5, the seventh core die 121-7 is stacked in the Z direction from the sixth core die 121-6, and the eight core die 121-8 is stacked in the Z direction from the seventh core die 121-7.

Various control circuits that control the core die group 121 may be disposed beneath the second region 115 of the base die 111. The control circuits disposed beneath the second region 115 may include write control circuits (not shown) that store data in the core die group 121 and read control circuits (not shown) that output data from the core die group 121.

As described above, an empty space is provided in the Z direction from the first region 113 of the base die 111, and the heat generated by the operation of the internal circuits located beneath the first region 113 is dissipated in the Z direction from the first region 113. This configuration helps prevent the internal temperature of the base die 111 from rising excessively.

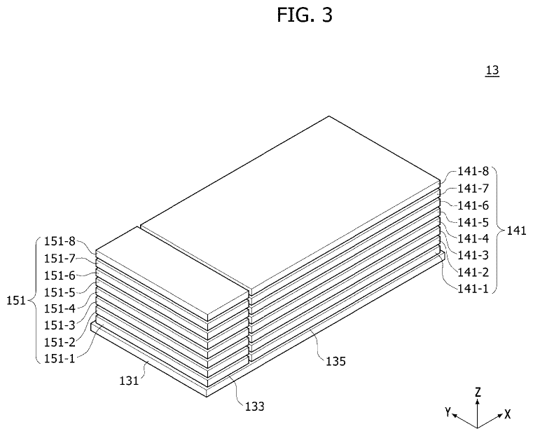

FIG. 3 illustrates a stacked memory device 13 according to an embodiment of the present disclosure.

As shown in FIG. 3, the stacked memory device 13 includes a base die 131 and a core die group 141. As in the embodiment described in relation to FIG. 2, the base die 131 includes a first region 133 and a second region 135 on the XY plane.

A physical layer that controls transmission of signals (for example, data, commands, and addresses) through a plurality of channels between the core die group 141 and a processor (for example, a processor 49 in FIG. 9) may be disposed beneath the first region 133 of the base die 131. According to embodiments, circuits that operate in a high-temperature state due to frequent input/output of signals, among internal circuits included in the base die 131, may be disposed beneath the first region 133 of the base die 131. A plurality of dummy dies 151-1 through 151-8 of a dummy die group 151 are stacked to dissipate heat in the Z direction from the first region 133 of the base die 131. The dummy die group 151 includes a first dummy die 151-1, a second dummy die 151-2, a third dummy die 151-3, a fourth dummy die 151-4, a fifth dummy die 151-5, a sixth dummy die 151-6, a seventh dummy die 151-7, and an eighth dummy die 151-8. The first dummy die 151-1 is stacked in the Z direction from the first region 133, the second dummy die 151-2 is stacked in the Z direction from the first dummy die 151-2, the third dummy die 151-3 is stacked in the Z direction from the second dummy die 151-2, the fourth dummy die 151-4 is stacked in the Z direction from the third dummy die 151-3, the fifth dummy die 151-5 is stacked in the z direction from the fourth dummy die 151-4, the sixth dummy die 151-6 is stacked in the z direction from the fifth dummy die 151-5, the seventh dummy die 151-7 is stacked in the Z direction from the sixth dummy die 151-6, and the eighth dummy die 151-8 is stacked in the Z direction from the seventh dummy die 151-7. The dummy dies 151-1 through 151-8 of the dummy die group 151 are stacked in the Z direction from the first region 133 of the base die 131, and thus, heat generated from the internal circuits located beneath the first region 133 of the base die 131 during operation can be dissipated in the Z direction from the first region 133 through the dummy die group 151. The first dummy die 151-1, the second dummy die 151-2, the third dummy die 151-3, the fourth dummy die 151-4, the fifth dummy die 151-5, the sixth dummy die 151-6, the seventh dummy die 151-7, and the eighth dummy die 151-8 are connected through a plurality of through vias and a plurality of micro-bump pads to each other to facilitate heat dissipation.

A plurality of core dies 141-1 through 141-8 of the core die group 141 are stacked in the Z direction from the second region 135. The core die group 141 includes a first core die 141-1, a second core die 141-2, a third core die 141-3, a fourth core die 141-4, a fifth core die 141-5, a sixth core die 141-6, a seventh core die 141-7, and an eighth core die 141-8. The first core die 141-1 is stacked in the Z direction from the second region 135, the second core die 141-2 is stacked in the Z direction from the first core die 141-1, the third core die 141-3 is stacked in the Z direction from the second core die 141-2, the fourth core die 141-4 is stacked in the Z direction from the third core die 141-3, the fifth core die 141-5 is stacked in the Z direction from the fourth core die 141-4, the sixth core die 141-6 is stacked in the Z direction from the fifth core die 141-5, the seventh core die 141-7 is stacked in the Z direction from the sixth core die 141-6, and the eighth core die 141-8 is stacked in the Z direction from the seventh core die 141-7.

Various control circuits that control the core die group 141 may be disposed beneath the second region 135 of the base die 131. The control circuits disposed beneath the second region 135 may include write control circuits (not shown) that store data in the core die group 141 and read control circuits (not shown) that output data from the core die group 141.

As described above, the dummy dies of the dummy die group 151 are stacked in the Z direction from the first region 133 of the base die 131, and thus, the heat generated during operation of the internal circuits located beneath the first region 133 can be dissipated through the dummy die group 151 in the Z direction from the first region 133. This configuration helps prevent the internal temperature of the base die 131 from rising excessively.

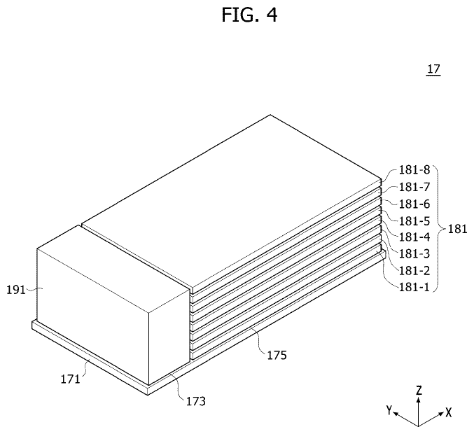

FIG. 4 illustrates a stacked memory device 17 according to an embodiment of the present disclosure.

As shown in FIG. 4, the stacked memory device 17 includes a base die 171 and a core die group 181. As in the embodiment shown in FIG. 2, the base die 171 includes a first region 173 and a second region 175 on the XY plane of the base die 171.

A physical layer that controls transmission of signals (for example, data, commands, and addresses) through a plurality of channels between the core die group 181 and a processor (for example, a processor 49 in FIG. 9) may be disposed beneath the first region 173 of the base die 171. According to embodiments, circuits that operate in a high-temperature state due to frequent input/output of signals, among internal circuits included in the base die 171, may be disposed beneath the first region 173 of the base die 171. A dummy die 191 is disposed to dissipate heat in the Z direction from the first region 133 of the base die 171.

A plurality of core dies 181-1 through 181-8 of the core die group 181 are stacked in the Z direction from the second region 175. The core die group 181 includes a first core die 181-1, a second core die 181-2, a third core die 181-3, a fourth core die 181-4, a fifth core die 181-5, a sixth core die 181-6, a seventh core die 181-7, and an eighth core die 181-8. The first core die 181-1 is stacked in the Z direction from the second region 175. The second core die 181-2 is stacked in the Z direction from the first core die 181-1, the third core die 181-3 is stacked in the Z direction from the second core die 181-2, the fourth core die 181-4 is stacked in the Z direction from the third core die 181-3, the fifth core die 181-5 is stacked in the Z direction from the fourth core die 181-4, the sixth core die 181-6 is stacked in the Z direction from the fifth core die 181-5, the seventh core die 181-7 is stacked in the Z direction from the sixth core die 181-6, and the eighth core die 181-8 is stacked in the Z direction from the seventh core die 181-7.

Various control circuits that control the core die group 181 may be disposed beneath the second region 175 of the base die 171. The control circuits disposed beneath the second region 175 may include write control circuits (not shown) that store data in the core die group 181 and read control circuits (not shown) that output data from the core die group 181.

As discussed above, the dummy die 191 is disposed in the Z direction from the first region 173 of the base die 171, and thus, the heat generated from the internal circuits located beneath the first region 173 during operation can be dissipated through the dummy die 191 in the Z direction from the first region 173. This configuration helps prevent the internal temperature of the base die 171 from rising excessively.

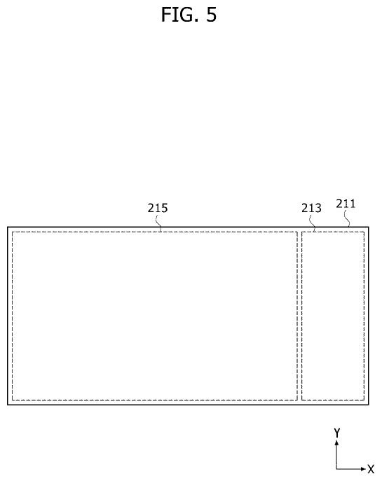

FIG. 5 to FIG. 8 illustrate examples of the arrangement of regions included in a base die.

As shown in FIG. 5, a base die 211 includes a first region 213 and a second region 215 on the XY plane. The first region 213 and the second region 215 are sequentially arranged adjacent to each other in the X direction. The first region 213 may correspond to the first region 113 as shown in FIG. 1 and FIG. 2 and may correspond to the first region 133 as shown in FIG. 3 and the first region 173 as shown in FIG. 3. Accordingly, a physical layer that controls transmission of signals (for example, data, commands, and addresses) through a plurality of channels may be disposed beneath the first region 213, and an empty space may be provided on the first region 213 or at least one dummy die may be disposed on the first region 213, thereby dissipating the heat generated in internal circuits beneath the first region 213.

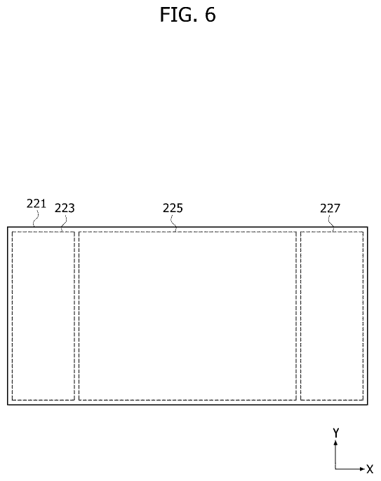

As shown in FIG. 6, a first region 223, a second region 225, and a third region 227 are arranged on the XY plane of a base die 221. The first region 223, the second region 225, and the third region 227 are arranged to be adjacent to each other in the X direction. The first region 223 and the third region 227 may correspond to the first region 113 as shown in FIG. 1 and FIG. 2, the first region 133 as shown in FIG. 3, and the first region 173 as shown in FIG. 4. Accordingly, a physical layer that controls transmission of signals (for example, data, commands, and addresses) through a plurality of channels may be disposed beneath the first region 223 and the third region 227, and an empty space may be provided on the first region 223 and the third region 227 or at least one dummy die may be disposed on the first region 223 and the third region 227, thereby dissipating the heat generated in the internal circuits beneath the first region 223 and the third region 227.

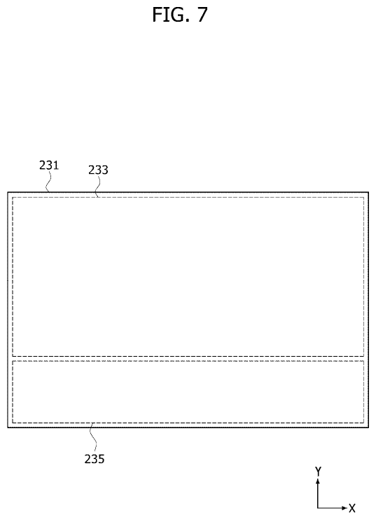

As shown in FIG. 7, a first region 235 and a second region 233 are arranged on the XY plane of a base die 231. The first region 235 and the second region 235 are arranged to be adjacent in the Y direction. The first region 235 may correspond to the first region 113 as shown in FIG. 1 and FIG. 2, the first region 133 as shown in FIG. 3, and the first region 173 as shown in FIG. 4. Accordingly, a physical layer that controls transmission of signals (for example, data, commands, and addresses) through a plurality of channels may be disposed beneath the first region 235, and an empty space may be provided on the first region 235 or at least one dummy die may be disposed on the first region 235, thereby dissipating the heat generated in the internal circuits beneath the first region 235.

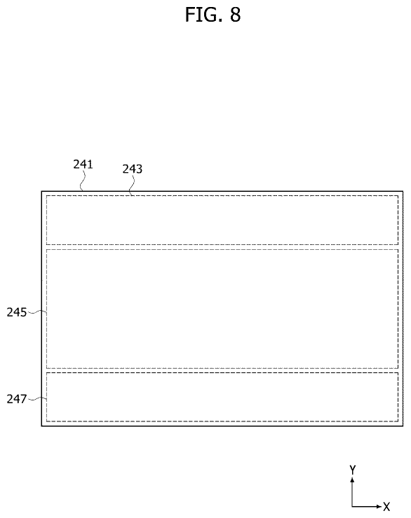

As shown in FIG. 8, a first region 243, a second region 245, and a third region 247 are arranged on the XY plane of a base die 241. The third region 247, the second region 245, and the first region 243 are sequentially arranged in the Y direction. Each of the first region 243 and the third region 247 may correspond to the first region 113 as shown in FIG. 1 and FIG. 2, the first region 133 as shown in FIG. 3, and the first region 173 as shown in FIG. 4. Accordingly, a physical layer that controls transmission of signals (for example, data, commands, and addresses) through a plurality of channels may be disposed beneath the first region 243 and the third region 247, and empty spaces may be provided on the first region 243 and the third region 247 or at least one dummy die may be disposed on the first region 243 and the third region 247, thereby dissipating the heat generated in the internal circuits beneath the first region 243 and the third region 247.

FIG. 9 illustrates a memory system 4 according to an embodiment of the present disclosure.

As shown in FIG. 9, the memory system 4 includes a printed circuit board (PCB) 41, a substrate 43, an interposer 45, a memory device 47, and a processor 49.

The printed circuit board 41 connects various electronic components to each other to form electronic circuits. The electronic circuits include the memory system 4. A copper (Cu) layer, a solder mask, a silk screen, and so forth are formed on the printed circuit board 41. Circuit paths that transmit or transfer signals or power are formed in the copper (Cu) layer. The solder mask prevents damage to the circuits and protects a specific region where components are soldered. The silk screen indicates a location or information for the electronic components as characters or symbols printed on a surface of the printed circuit board 41.

The substrate 43 is disposed over the printed circuit board 41 with bump pads (for example, bump pads 411) therebetween and mechanically supports the interposer 45, the memory device 47, and the processor 49. The substrate 43 functions as a physical base for the printed circuit board 41 and is an insulator. The substrate 43 may include materials, such as FR4 that is an insulator made of fiberglass and epoxy resin, ceramics that can withstand high temperatures, have appropriate thermal conductivity properties, and are used in high-frequency circuits, polyimide that is used as a basic material for flexible PCBs due to flexible characteristics, and the like.

The interposer 45 is disposed over the substrate 43 with bump pads therebetween and includes wiring that connects electronic components (for example, the memory device 47 and the processor 49) that have form factors or pin arrangements that do not match or have different spacing. The interposer 45 converts signals from different interfaces, such as DDR, HBM, and PCIe.

The memory device 47 is disposed over the interposer 45 with pads (for example, micro bump pads 413) therebetween. The memory device 47 stores data received from the processor 49 or outputs the stored data to the processor 49 under the control of the processor 49. The memory device 47 includes a base die 420 and a plurality of core dies 421-1 through 421-L, where L is an integer greater than 1. The core dies 421-1 through 421-L are stacked over the base die 420 with micro bump pads in between. The base die 420 and the core dies 421-1 through 421-L are vertically connected to each other using through vias and micro bump pads. The base die 420 controls efficient data transmission between the processor 49 and the core dies 421-1 through 421-L. The base die 420 receives input/output power voltage (voltage drain for IO also referred to as output stage drain power voltage) VDDQ as an operating voltage utilized during the operation of internal circuits included in the base die 420. The base die 420 receives the input/output power voltage VDDQ from the printed circuit board 41 through the substrate 43 and the interposer 45. The input/output power voltage VDDQ is a voltage supplied to buffers that transmit data and is distinguished or different from the power supply voltage VDD. The core dies 421-1 through 421-L use a peripheral voltage VPERI as an operating voltage during the operation of the internal circuits included in the core dies 421-1 through 421-L. The core dies 421-1 through 421-L generate the peripheral voltage VPERI from the input/output power voltage VDDQ received through the base die 420. The core dies 421-1 through 421-L generate the peripheral voltage VPERI at a lower voltage level than the input/output power voltage VDDQ and use the peripheral voltage VPERI as an operating voltage. Each of the core dies 421-1 through 421-L includes a plurality of channel regions, for example, eight channel regions or forty-six channel regions that operate independently. Each of the plurality of channel regions is allocated with a channel operating independently to receive or transmit data. The number L of core dies 421-1 through 421-L may be four, eight, thirty-two, forty-six, and so forth. For example, when each of the core dies 421-1 through 421-12 has eight channels, the core dies 421-1 through 421-4, the core dies 421-5 through 421-8, and the core dies 421-9 through 421-12 each include thirty-two channel regions and transmit and receive data with the processor 49 in units of a rank including thirty-two channels.

The memory device 47 may be implemented with the stacked memory device 11 as shown in FIG. 1, the stacked memory device 13 as shown in FIG. 3, and stacked memory device 17 as shown in FIG. 4. The base die 420 may be implemented with the base die 111 as shown in FIG. 1 and FIG. 2, the base die 131 as shown in FIG. 3, the base die 171 as shown in FIG. 4, the base die 211 as shown in FIG. 5, the base die 221 as shown in FIG. 6, the base die 231 as shown in FIG. 7, and the base die 241 as shown in FIG. 8.

Concepts are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. The scope of the present disclosure is not limited to the descriptions. All changes within the meaning and range of equivalency of the claims are included within their scope.

What is claimed is:

1. A stacked memory device comprising:
a first die including a first region and a second region, the first die being on a plane defined by a first direction and a second direction; and
a die group stacked on the second region,
wherein a first layer is disposed beneath the first region, the first layer controlling transmission of signals between the die group and a processor through a plurality of channels, and
wherein an empty space is provided over the first region.

2. The stacked memory device of claim 1, wherein control circuits that store or output data in or from the die group are disposed beneath the second region.

3. The stacked memory device of claim 1, wherein the die group includes a plurality of second dies sequentially stacked on the second region.

4. The stacked memory device of claim 1, wherein the first region and the second region are arranged on the plane of the first die to be adjacent to each other in the second direction.

5. The stacked memory device of claim 1,
wherein the first die further includes a third region on the plane of the first die,
wherein a second layer is disposed beneath the third region, and
wherein an empty space is provided over the third region.

6. A stacked memory device comprising:
a first die including a first region and a second region, the first die being on a plane defined by a first direction and a second direction; and
a die group stacked on the second region,
wherein a first layer is disposed beneath the first region, the first layer controlling transmission of signals between the die group and a processor through a plurality of channels, and
wherein a first dummy die group is stacked on the first region.

7. The stacked memory device of claim 6, wherein the first dummy die group includes a plurality of first dummy dies that are sequentially stacked on the first region in the first direction.

8. The stacked memory device of claim 7, wherein the plurality of first dummy dies are connected to each other through a plurality of through vias and a plurality of micro bump pads.

9. The stacked memory device of claim 6, wherein the die group includes a plurality of second dies that are sequentially stacked on the second region.

10. The stacked memory device of claim 6, wherein the first region and the second region are arranged on the plane of the first die to be adjacent to each other in the second direction.

11. The stacked memory device of claim 6,
wherein the first die further includes a third region on the plane of the first die,
wherein a second layer is disposed beneath the third region, and
wherein a second dummy die group is stacked on the third region.

12. The stacked memory device of claim 11, wherein the second dummy die group includes a plurality of second dummy dies that are sequentially stacked on the third region.

13. The stacked memory device of claim 12, wherein the plurality of second dummy dies are connected to each other through a plurality of through vias and a plurality of micro bump pads.

14. A stacked memory device comprising:
a first die including a first region and a second region, the first die being on a plane defined by a first direction and a second direction; and
a core die group stacked on the second region,
wherein a first layer is disposed beneath the first region of the first die, the first layer controlling transmission of signals between the die group and a processor through a plurality of channels, and
wherein a first dummy die is disposed on the first region.

15. The stacked memory device of claim 14, wherein the core die group includes a plurality of second dies that are sequentially stacked on the second region.

16. The stacked memory device of claim 14, wherein the first region and the second region are disposed on the plane of the first die to be adjacent to each other in the second direction.

17. The stacked memory device of claim 14,
wherein the first die further includes a third region on the plane of the first die,
wherein a second layer is disposed beneath the third region, and
wherein a second dummy die is stacked on the third region.
